(19) United States
(12) Patent Application Publication
(10) Pub. No.: US 2025/0379559 A1
(43) Pub. Date: Dec. 11, 2025

(54) BULK ACOUSTIC WAVE DUPLEXER INCLUDING RESONATORS HAVING TOP AND BOTTOM MASS LOADS

(71) Applicant: Skyworks Solutions, Inc., Irvine, CA (US)

(72) Inventors: Benjamin Paul Abbott, Irvine, CA (US); Tomoya Komatsu, Irvine, CA (US); Martha Kennedy Small, Fort Collins, CO (US); Li Chen, Irvine, CA (US)

(21) Appl. No.: 19/230,534

(22) Filed: Jun. 6, 2025

Related U.S. Application Data
(60) Provisional application No. 63/657,186, filed on Jun. 7, 2024.

(51) Int. Cl. H03H 9/70; H03H 9/205; H03H 9/56

(52) U.S. Cl. CPC H03H 9/706; H03H 9/205; H03H 9/568

(57) ABSTRACT

Aspects and embodiments disclosed herein include a die comprising a plurality of bulk acoustic wave resonators. Each of the plurality of bulk acoustic wave resonators includes a piezoelectric material film having an active region. The plurality of bulk acoustic wave resonators include a first subset with metallic mass loading layers disposed above an upper electrode disposed on the piezoelectric material film in the active region and a second subset with metallic mass loading layers disposed below a lower electrode disposed on the piezoelectric film in the active region to cause the first subset to exhibit a different operating frequency than the second subset.

### CROSS-REFERENCE TO RELATED APPLICATIONS

This application claims priority under 35 U.S.C. § 119 (e) to U.S. Provisional Patent Application Ser. No. 63/657,186, titled “BULK ACOUSTIC WAVE DUPLEXER INCLUDING RESONATORS HAVING TOP AND BOTTOM MASS LOADS,” filed Jun. 7, 2024, the entire content of which is incorporated herein by reference or all purposes.

### TECHNICAL FIELD

Embodiments of this disclosure relate to die including multiple bulk acoustic wave resonators having different operating frequencies and both top and bottom mass loading layers.

### DESCRIPTION OF RELATED TECHNOLOGY

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a die comprising a plurality of bulk acoustic wave resonators, each of the plurality of bulk acoustic wave resonators including a piezoelectric material film having an active region, the plurality of bulk acoustic wave resonators including a first subset with metallic mass loading layers disposed above an upper electrode disposed on the piezoelectric material film in the active region and a second subset with metallic mass loading layers disposed below a lower electrode disposed on the piezoelectric material film in the active region to cause the first subset to exhibit a different operating frequency than the second subset.

In some embodiments, the plurality of bulk acoustic wave resonators form a first radio frequency filter and a second radio frequency filter, the first radio frequency filter and the second radio frequency filter having non-overlapping passbands.

In some embodiments, the first radio frequency filter and the second radio frequency filter form a duplexer.

In some embodiments, the first radio frequency filter and the second radio frequency filter are configured as ladder filters, each including series arm resonators and shunt arm resonators selected from among the plurality of bulk acoustic wave resonators.

In some embodiments, the shunt arm resonators of each of the first radio frequency filter and the second radio frequency filter have a same mass loading.

In some embodiments, the series arm resonators of each of the first radio frequency filter and the second radio frequency filter have a same mass loading.

In some embodiments, the series resonators of the one of the first radio frequency filter and the second radio frequency filter having the higher operating frequency have a lowest mass loading among the series arm and shunt arm resonators of the first radio frequency filter and the second radio frequency filter.

In some embodiments, the shunt resonators of the one of the first radio frequency filter and the second radio frequency filter having the higher operating frequency have a same mass loading.

In some embodiments, the bulk acoustic wave resonators of the one of the first radio frequency filter and the second radio frequency filter having the lower operating frequency have a greater mass loading than the bulk acoustic wave resonators of the one of the first radio frequency filter and the second radio frequency filter having the higher operating frequency.

In some embodiments, at least one bulk acoustic wave resonator in each of the first radio frequency filter and the second radio frequency filter includes a metallic mass loading layer disposed above the upper electrode disposed on the piezoelectric material film in the active region and at least one bulk acoustic wave resonator in each of the first radio frequency filter and the second radio frequency filter includes a metallic mass loading layer disposed below the lower electrode disposed on the piezoelectric material film in the active region.

In some embodiments, at least one series arm resonator in one of the first radio frequency filter or the second radio frequency filter includes the metallic mass loading layer disposed above the upper electrode disposed on the piezoelectric material film in the active region and at least one shunt arm resonator in the one of the first radio frequency filter or the second radio frequency filter includes the metallic mass loading layer disposed below the lower electrode disposed on the piezoelectric material film in the active region.

In some embodiments, at least one shunt arm resonator in one of the first radio frequency filter or the second radio frequency filter includes the metallic mass loading layer disposed above the upper electrode disposed on the piezoelectric material film in the active region and at least one series arm resonator in the one of the first radio frequency filter or the second radio frequency filter includes the metallic mass loading layer disposed below the lower electrode disposed on the piezoelectric material film in the active region.

In some embodiments, at least one shunt arm resonator of the first radio frequency filter includes a first metallic mass loading layer disposed above the upper electrode disposed on the piezoelectric material film in the active region and at least one shunt arm resonator of the second radio frequency filter includes a second metallic mass loading layer disposed above the upper electrode disposed on the piezoelectric material film in the active region, the first metallic mass loading layer having a different thickness than the second metallic mass loading layer.

In some embodiments, at least one shunt arm resonator of the first radio frequency filter includes a first metallic mass loading layer disposed above the upper electrode disposed on the piezoelectric material film in the active region and at least one shunt arm resonator of the second radio frequency filter includes a second metallic mass loading layer disposed below the lower electrode disposed on the piezoelectric material film in the active region, the first metallic mass loading layer having a different thickness than the second metallic mass loading layer.

In some embodiments, at least one shunt arm resonator of the first radio frequency filter includes a first metallic mass loading layer disposed above the upper electrode disposed on the piezoelectric material film in the active region and at least one series arm resonator of the second radio frequency filter includes a second metallic mass loading layer disposed below the lower electrode disposed on the piezoelectric material film in the active region, the first metallic mass loading layer having a different thickness than the second metallic mass loading layer.

In some embodiments, at least one shunt arm resonator of one of the first radio frequency filter or the second radio frequency filter includes two metallic mass loading layers disposed above the upper electrode disposed on the piezoelectric material film in the active region, the two metallic mass loading layers having different thicknesses.

In some embodiments, at least one shunt arm resonator of one of the first radio frequency filter or the second radio frequency filter includes two metallic mass loading layers disposed below the lower electrode disposed on the piezoelectric material film in the active region, the two metallic mass loading layers having different thicknesses.

In some embodiments, at least one shunt arm resonator of one of the first radio frequency filter or the second radio frequency filter includes a metallic mass loading layer disposed below the lower electrode disposed on the piezoelectric material film in the active region and a metallic mass loading layer disposed above the upper electrode disposed on the piezoelectric material film in the active region.

In some embodiments, at least one shunt arm resonator of the first radio frequency filter includes a first metallic mass loading layer disposed below the lower electrode disposed on the piezoelectric material film in the active region and at least one shunt arm resonator of the second radio frequency filter includes a second metallic mass loading layer disposed below the lower electrode disposed on the piezoelectric material film in the active region, the first metallic mass loading layer having a different thickness than the second metallic mass loading layer.

In some embodiments, at least one shunt arm resonator of the first radio frequency filter includes a first metallic mass loading layer disposed below the lower electrode disposed on the piezoelectric material film in the active region and at least one series arm resonator of the second radio frequency filter includes a second metallic mass loading layer disposed below the lower electrode disposed on the piezoelectric material film in the active region, the first metallic mass loading layer having a different thickness than the second metallic mass loading layer.

In some embodiments, the plurality of bulk acoustic wave resonators include resonators which form parts of at least three different radio frequency filters with different operating frequencies.

In some embodiments, the die is included in an electronic device module.

In some embodiments, the electronic device module is included in a radio frequency device.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a schematic illustration of a die including multiple film bulk acoustic wave resonators with different operating frequencies;

FIG. 3 is a schematic illustration of a portion of a radio frequency module including a die having multiple film bulk acoustic wave resonators with different operating frequencies;

FIG. 4 schematically illustrates mass loading layers that may be added above and below electrodes disposed on a piezoelectric material layer in an active region of a BAW resonator to adjust the operating frequency of the BAW resonator;

FIG. 5 illustrates one example of an arrangement of mass loading films on electrodes disposed on piezoelectric material layers in active regions of BAW resonators in ladder filters of a duplexer in which two upper mass loading films and one lower mass loading film may be utilized to adjust operating frequencies of the resonators;

FIG. 6 is a table listing materials and thicknesses of the layers utilized in the resonators of FIG. 5;

FIG. 7 illustrates another example of an arrangement of mass loading films on electrodes disposed on piezoelectric material layers in active regions of BAW resonators in ladder filters of a duplexer in which two upper mass loading films and one lower mass loading film may be utilized to adjust operating frequencies of the resonators;

FIG. 8 illustrates another example of an arrangement of mass loading films on electrodes disposed on piezoelectric material layers in active regions of BAW resonators in ladder filters of a duplexer in which two upper mass loading films and one lower mass loading film may be utilized to adjust operating frequencies of the resonators;

FIG. 9 illustrates another example of an arrangement of mass loading films on electrodes disposed on piezoelectric material layers in active regions of BAW resonators in ladder filters of a duplexer in which two upper mass loading films and one lower mass loading film may be utilized to adjust operating frequencies of the resonators;

FIG. 10 illustrates another example of an arrangement of mass loading films on electrodes disposed on piezoelectric material layers in active regions of BAW resonators in ladder filters of a duplexer in which two upper mass loading films and one lower mass loading film may be utilized to adjust operating frequencies of the resonators;

FIG. 11 illustrates one example of an arrangement of mass loading films on electrodes disposed on piezoelectric material layers in active regions of BAW resonators in ladder filters of a duplexer in which two lower mass loading films and one upper mass loading film may be utilized to adjust operating frequencies of the resonators;

FIG. 12 illustrates another example of an arrangement of mass loading films on electrodes disposed on piezoelectric material layers in active regions of BAW resonators in ladder filters of a duplexer in which two lower mass loading films and one upper mass loading film may be utilized to adjust operating frequencies of the resonators;

FIG. 13 illustrates another example of an arrangement of mass loading films on electrodes disposed on piezoelectric material layers in active regions of BAW resonators in ladder filters of a duplexer in which two lower mass loading films and one upper mass loading film may be utilized to adjust operating frequencies of the resonators;

FIG. 14 illustrates another example of an arrangement of mass loading films on electrodes disposed on piezoelectric material layers in active regions of BAW resonators in ladder filters of a duplexer in which two lower mass loading films and one upper mass loading film may be utilized to adjust operating frequencies of the resonators;

FIG. 15 illustrates another example of an arrangement of mass loading films on electrodes disposed on piezoelectric material layers in active regions of BAW resonators in ladder filters of a duplexer in which two lower mass loading films and one upper mass loading film may be utilized to adjust operating frequencies of the resonators;

FIG. 16 illustrates another example of an arrangement of mass loading films on electrodes disposed on piezoelectric material layers in active regions of BAW resonators in ladder filters of a duplexer in which two lower mass loading films and one upper mass loading film may be utilized to adjust operating frequencies of the resonators;

FIG. 17 is a schematic diagram of a radio frequency ladder filter;

FIG. 18 illustrates an embodiment of an electronics module;

FIG. 19 illustrates an example of a front-end module which may be used in an electronic device; and

FIG. 20 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally include a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined in part by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

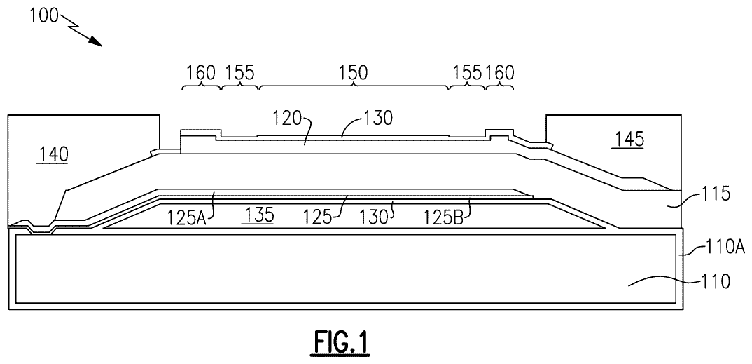

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 (often abbreviated MTE for Metal Top Electrode) is disposed on top of a portion of the layer or film of piezoelectric material 115 and a bottom electrode 125 (often abbreviated MBE for Metal Bottom Electrode) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

It should be appreciated that the BAW resonators and piezoelectric material layers illustrated in the figures are illustrated in a highly simplified form. The relative dimensions of the different features are not shown to scale. Further, typical BAW resonators may include additional features or layers not illustrated.

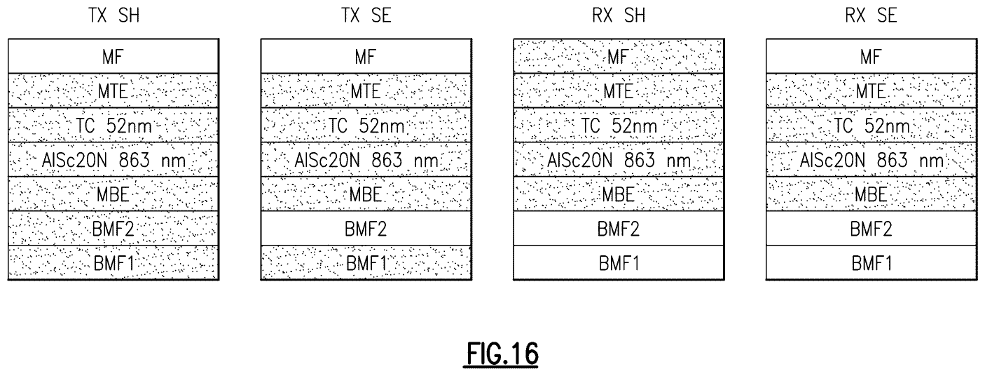

When BAW resonators are combined into a filter, different ones of the resonators may operate at different resonant and antiresonant frequencies. For example, when combined in a ladder filter (See FIG. 17 and discussion thereof below) the series resonators may operate at higher frequencies than the shunt resonators. In a duplexer, including both a transmission filter and a reception filter, the resonators of the reception filter may operate at higher frequencies than the resonators of the transmission filter. In a device utilizing multiple frequency bands, each of the resonators of filters associated with different ones of the frequency bands may operate at different frequencies. Often resonators formed on a single die are all fabricated using the same process and thus operate at the same resonant and antiresonant frequencies (hereinafter “operating frequency” or “operating frequencies”). One may then form, for example, a ladder filter by electrically connecting series resonators on one die to shunt resonators on a separate die. It has been realized that device footprint size, manufacturing cost, and variation in performance metrics may be reduced if one could form resonators with different operating frequencies on the same die and then form, for example, a filter, a duplexer (or triplexer, quadplexer, etc.) or portions or entire filters operating at different frequency bands on the same die.

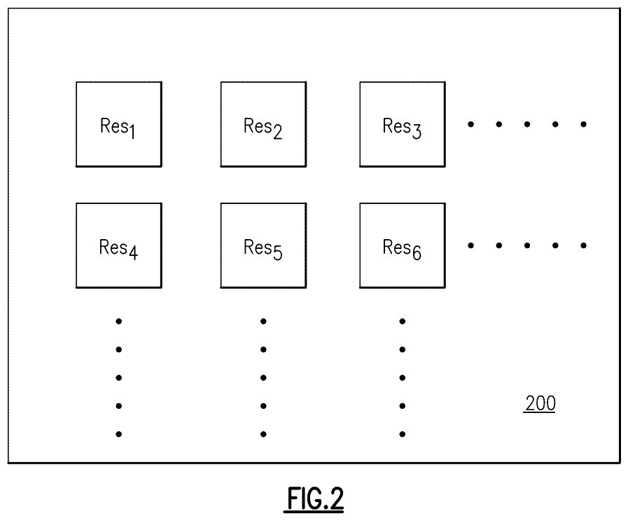

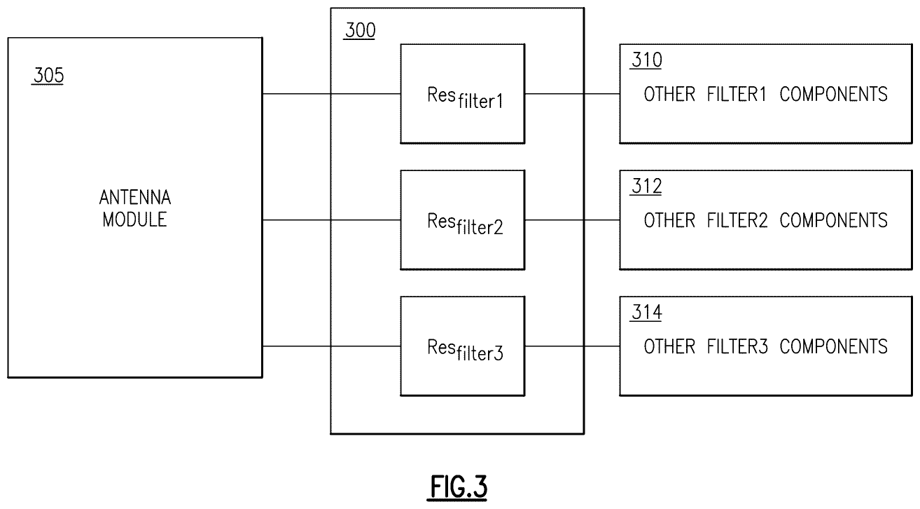

FIG. 2 schematically shows an example of a single die 200 including multiple BAW resonators Res₁-Res₆ (although more or fewer resonators may be present). One or more of the resonators Res₁-Res₆ may have a different operating frequency than one or more other of the resonators Res₁-Res₆. The different resonators Res₁-Res₆ may have more than two different operating frequencies. The different resonators Res₁-Res₆ may be electrically connected in one circuit to form a filter, duplexer, triplexer, or other circuit or one or more of the resonators Res₁-Res₆ may form part of a different circuit than one or more other of the resonators Res₁-Res₆. FIG. 3 illustrates an example where three different BAW resonators Res_{filter1}, Res_{filter2}, and Res_{filter3}, each forming part of a different filter are formed on the same die 300. Such an arrangement may be desirable if one wishes to maintain the same physical distance between each of the resonators on the die 300 and some other shared circuit component, for example, an antenna or antenna module 305 to facilitate impedance matching between the filters. Remaining components, for example, additional resonators of the different filters could be formed on other die 310, 312, 314 and electrically connected to the respective resonators on the shared die 300.

The operating frequency of a BAW resonator is dependent on the thickness of the piezoelectric material film within the BAW resonator, but also on the mass of electrodes or other structures formed on the piezoelectric material film in the central region 150. Generally, for BAW resonators with all else being equal, the more mass of material disposed on the piezoelectric material film, the lower the operating frequency of the resonator. To form a first resonator operating at a lower frequency than a second resonator one may, for example, deposit a thicker top electrode or a greater number or greater thickness of layers of metal or other material on the top of the piezoelectric material film of the first resonator than on the top of the piezoelectric material film of the second resonator. It has been found that one may achieve more control over operating frequency of BAW resonators if one were to add different masses not only to the top of the piezoelectric material film but also to the bottom of the piezoelectric material film.

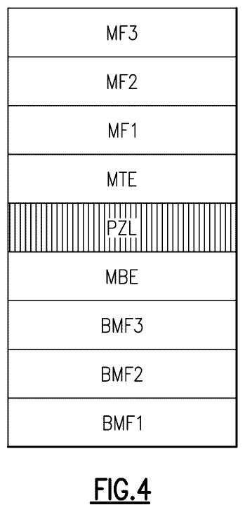

One example of a structure for adding mass loads to the piezoelectric material film within the central region 150 of a BAW resonator is illustrated in FIG. 4. This figure is highly schematic and conceptual in nature and omits many other films, such as adhesion or passivation layers that may be present in an actual BAW resonator. In FIG. 4, as well as the figures that follow, the term “MF” refers to a top electrode [M]ass load used to reduce the resonator's resonant [F]requency and the term “BMF” refers to a [B]ottom electrode [M]ass load used to reduce the resonator's resonant [F]requency. As shown in FIG. 4 in addition to the metal top electrode (“MTE”) disposed on top of the piezoelectric material film (“PZL”), one may also deposit one or more additional mass loading films MF1-MF3 above the piezoelectric material film. In some embodiments each of the different mass loading films MF1-MF3 have different masses per unit area, for example, different thicknesses. In addition to the metal bottom electrode (“MBE”) one may also form one or more additional mass loading films BMF1-BMF3 below the piezoelectric material film. In some embodiments each of the different mass loading films BMF1-BMF3 have different masses per unit area, for example, different thicknesses. The number, thickness, and material of mass loading films used may depend on what operating frequency is desired for the resonator. For resonators with a high target operating frequency one might not use any mass loading films. For resonators with a low target operating frequency one may utilize one or multiple MF and/or BMF mass loading films.

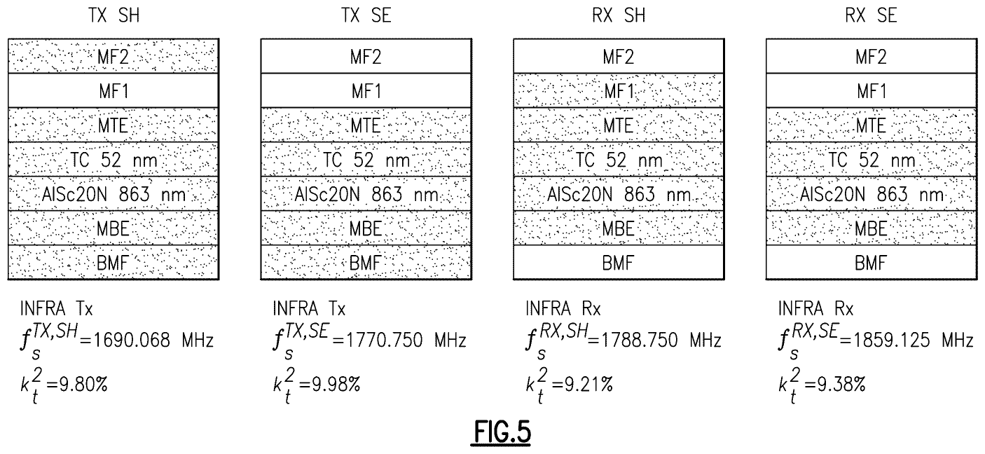

FIG. 5 illustrates the mass loading films that may be utilized in the BAW resonators of a non-limiting example of a Band 3 duplexer utilizing ladder filters where all the resonators are formed on the same die. The transmission (“TX”) filter resonators have two groups of resonant frequencies—the resonant frequency of the shunt resonators of the transmission filter (fₛ^{TX,SH}) and the resonant frequency of the series resonators of the transmission filter (fₛ^{TX,SE}). The reception (“RX”) filter resonators have two groups of resonant frequencies—the resonant frequency of the shunt resonators of the reception filter (fₛ^{RX,SH}) and the resonance frequency of the series resonators of the reception filter (fₛ^{RX,SE}). The mass load layers that are utilized are illustrated with cross-hatching. Mass load layers that do not include cross-hatching are not present but their positions, if they were to be present, are still illustrated. Each of the resonator types in the example of FIG. 5 include an 863 nm thick AlN piezoelectric material film doped with 20% scandium (“AlSc20N 863 nm”) covered with a 52 nm thick temperature compensation (“TC”) layer, metal bottom electrodes disposed below the piezoelectric material film and metal top electrodes disposed on the TC layer. The series resonators of the reception filter have the highest resonant frequency at 1859.125 MHz and do not include any mass loading layers. The shunt resonators of the reception filter have the second highest resonant frequency at 1788.750 MHz and include one MF mass loading layer (“MF1”). The series resonators of the transmission filter have the third highest resonant frequency at 1770.750 MHz and include one BMF mass loading layer (“BMF”). The shunt resonators of the transmission filter have the lowest resonant frequency at 1690.068 MHZ and include one MF mass loading layer (“MF2”) and one BMF mass loading layer. It should be appreciated that the MF1 mass loading layer is not present in the shunt resonators of the transmission filter so the MF2 film would be the only dominant mass loading layer on top of the piezoelectric material film.

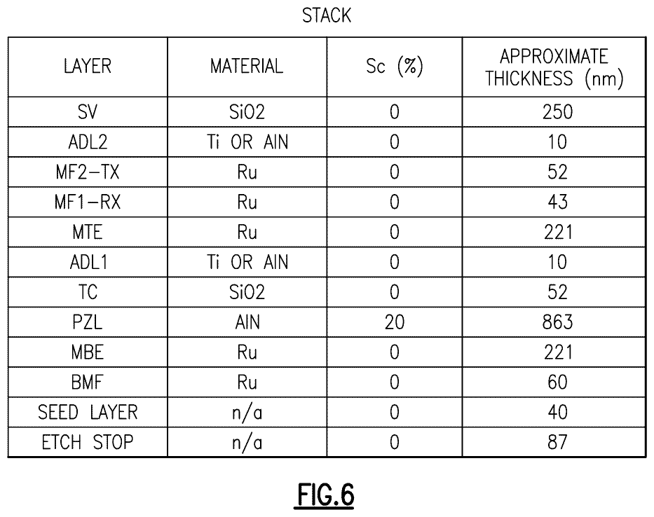

Specifics of materials and layer thicknesses that may be used in the resonator material layer stacks of FIG. 5 are shown in the table of FIG. 6. The three different mass lading layers MF2, MF1, and BMF may all be formed of the same material, for example, Ru, but may have different thicknesses to provide for flexibility in selecting a mass loading layer or group of mass loading layers that would cause a resonator to exhibit a desired operating frequency. It is to be noted that in addition to the layers illustrated in FIG. 5, in practice the resonators may include, for example, one or more adhesion layers (“ADL1,” “ADL2”), a passivation layer (“SV”), a seed layer, and an etch stop layer. One or more additional mass loading layers may be provided above or below the piezoelectric material layer in different embodiments.

In some embodiments, each of the MF1 mass loading layers of each of the resonators is deposited in the same process step, for example, a metal 1 deposition step. Similarly each of the MF2 mass loading layers of each of the resonators may be deposited in the same process step, for example, a metal 2 deposition step, and each of the MBF mass loading layers of each of the resonators may be deposited in the same process step. In embodiments with both an MBF1 mass loading layer and an BMF2 mass loading layer, the MBF1 mass loading layers on all resonators including it may be formed in the same process step and the MBF2 mass loading layers on all resonators including it may be formed in the same process step.

In various embodiments in which a duplexer is formed from ladder filters with all resonators of the ladder filters on a single die, three dominant mass loads may be utilized to produce four groupings of resonators (i.e., the series and shunt resonators of the transmission and reception filters of the duplexer). The three dominant mass loads may include two MF mass loading layers and one BMF mass loading layer. In other embodiments discussed below, the three dominant mass loads may include two BMF mass loading layers and one MF mass loading layer.

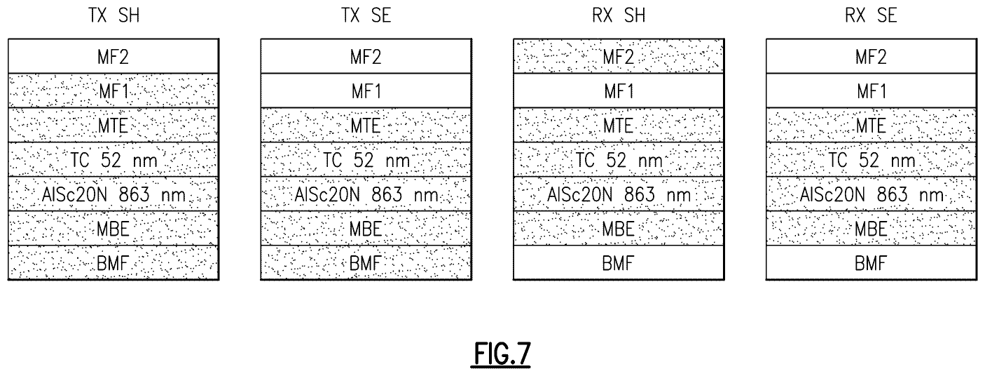

A variation on the stack structure for a Band 3 duplexer illustrated in FIG. 5 is shown in FIG. 7. The variation illustrated in FIG. 7 differs from that illustrated in FIG. 5 in that the shunt resonators of the reception filter utilize an MF2 mass loading layer instead of an MF1 mass load layer. The MF1 mass loading layer is not present in the shunt resonators of the reception filter so the MF2 mass loading layer is the only dominant mass loading layer above the piezoelectric material layer. The variation illustrated in FIG. 7 also differs from that illustrated in FIG. 5 in that the shunt resonators of the transmission filter utilize an MF1 mass loading layer instead of an MF2 mass loading layer.

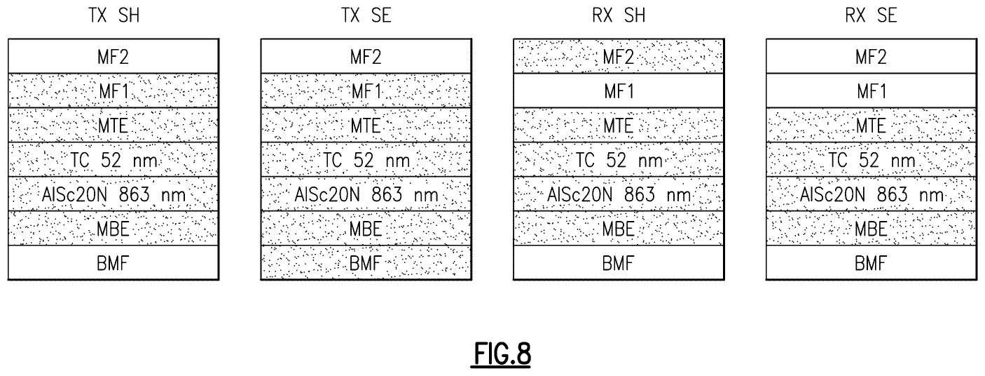

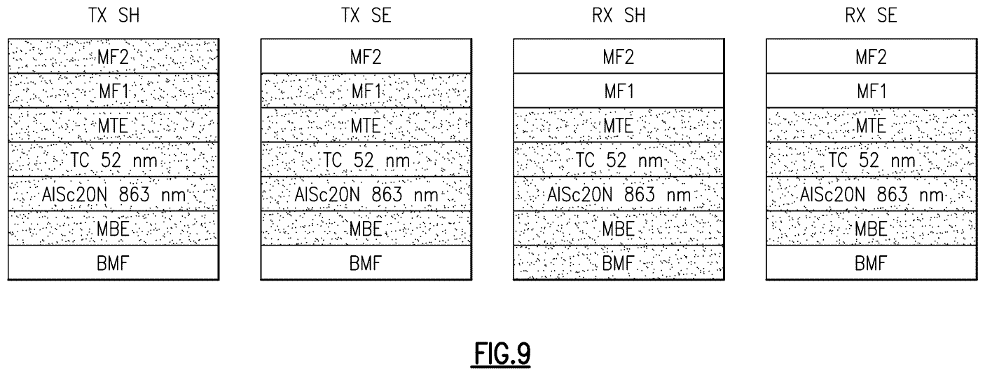

Another variation on the resonator stack structure illustrated in FIG. 5 is shown in FIG. 8. The variation shown in FIG. 8 differs from that shown in FIG. 5 in that the shunt resonators of the reception filter utilize an MF2 mass loading layer instead of an MF1 mass loading layer. The MF1 mass load layer is not present in the shunt resonators of the reception filter so the MF2 mass load layer is the only dominant mass loading layer above the piezoelectric material layer. The variation illustrated in FIG. 8 also differs from that illustrated in FIG. 5 in that the series resonators of the transmission filter utilize an MF1 mass loading layer in addition to the BMF mass loading layer, and the shunt resonators of the transmission filter utilize an MF1 mass loading layer instead of an MF2 mass load layer and do not utilize a BMF mass loading layer. Another variation on the resonator stack structure illustrated in FIG. 5 is shown in FIG. 9. The variation shown in FIG. 9 differs from that shown in FIG. 5 in that the shunt resonators of the reception filter utilize an BMF mass loading layer instead of an MF1 mass loading layer. The variation illustrated in FIG. 9 also differs from that illustrated in FIG. 5 in that the series resonators of the transmission filter utilize an MF1 mass loading layer instead of a BMF mass loading layer and the shunt resonators of the transmission filter utilize an MF1 mass loading layer instead of a BMF mass loading layer.

Another variation on the resonator stack structure illustrated in FIG. 5 is shown in FIG. 10. The variation shown in FIG. 10 differs from that shown in FIG. 5 in that the series resonators of the transmission filter utilize an MF2 mass loading layer instead of a BMF mass loading layer.

In other embodiments, in which a duplexer is formed from ladder filters with all resonators of the ladder filters on a single die, the three dominant mass loads that may be utilized to produce the four groupings of resonators (the series and shunt resonators of the transmission and reception filters of the duplexer) may include one MF layer and two BMF layers. BMF1 layers for each resonator in which this layer is used may be deposited in the same process step and BMF2 layers for each resonator in which this layer is used may be deposited in the same process step.

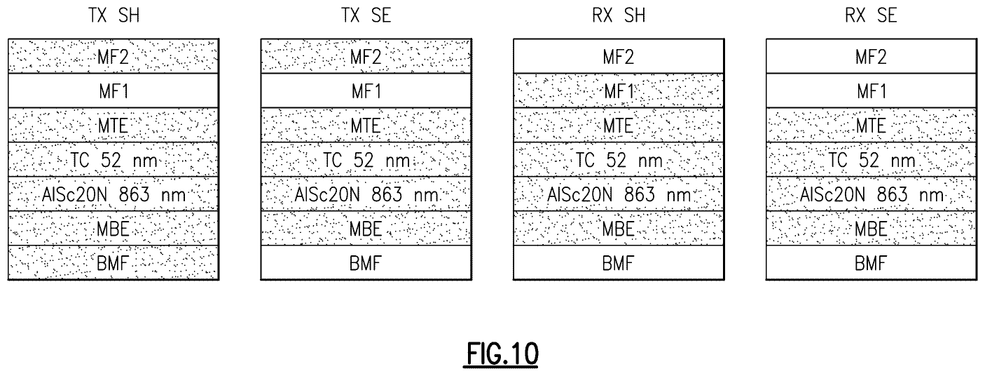

One example of an embodiment wherein the resonators of a duplexer formed on a single die utilize one MF mass loading layer and two BMF mass loading layers is shown in FIG. 11. In the embodiment shown in FIG. 11, the series resonators of the reception filter do not include any mass loading layers. The shunt resonators of the reception filter include one BMF1 mass loading layer and no MF mass loading layers. The series resonators of the transmission filter include one MF mass loading layer and no BMF mass loading layers. The shunt resonators of the transmission filter include one MF mass loading layer and one BMF2 mass loading layer. It should be appreciated that the BMF2 mass loading layer is not present in the shunt resonators of the reception filter so the BMF1 mass loading layer is the only dominant mass loading layer below the piezoelectric material layer in the reception filter shunt resonators.

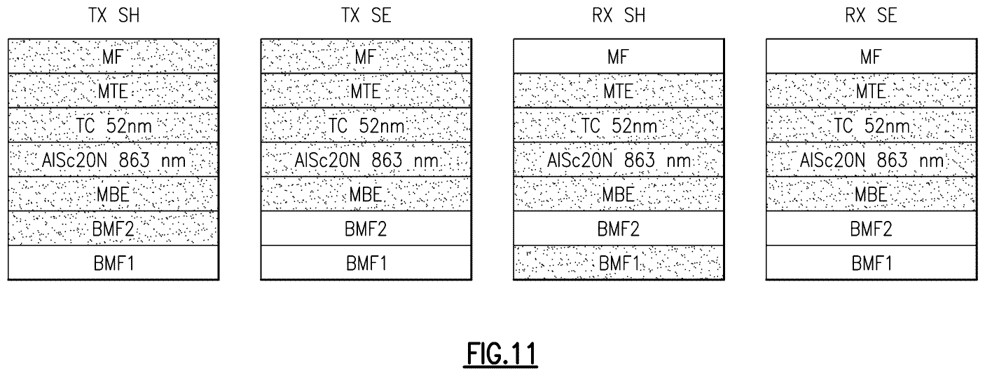

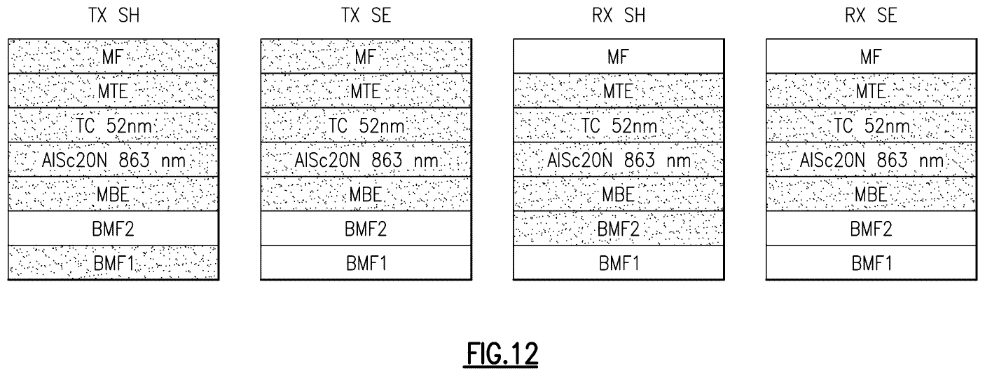

A variation on the stack structure for a Band 3 duplexer illustrated in FIG. 11 is shown in FIG. 12. The variation illustrated in FIG. 12 differs from that illustrated in FIG. 11 in that the shunt resonators of the reception filter utilize a BMF2 mass loading layer instead of a BMF1 mass loading layer. The variation illustrated in FIG. 12 also differs from that illustrated in FIG. 11 in that the shunt resonators of the transmission filter utilize a BMF1 mass loading layer instead of a BMF2 mass loading layer. The BMF2 mass loading layer is not present in the shunt resonators of the reception filter so the BMF1 mass loading layer is the only dominant mass loading layer below the piezoelectric material layer in the reception filter shunt resonators.

Another variation on the stack structure for a Band 3 duplexer illustrated in FIG. 11 is shown in FIG. 13. The variation illustrated in FIG. 13 differs from that illustrated in FIG. 11 in that the shunt resonators of the reception filter utilize a BMF2 mass loading layer instead of a BMF1 mass loading layer. The variation illustrated in FIG. 13 also differs from that illustrated in FIG. 11 in that the shunt resonators of the transmission filter utilize a BMF1 mass loading layer instead of a BMF2 mass loading layer. The BMF2 mass loading layer is not present in the shunt resonators of the reception filter so the BMF1 mass loading layer is the only dominant mass loading layer below the piezoelectric material layer of the reception filter shunt resonators.

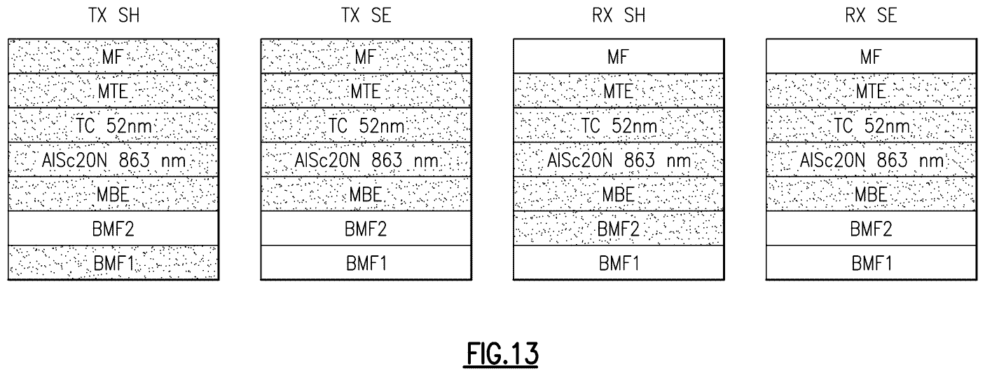

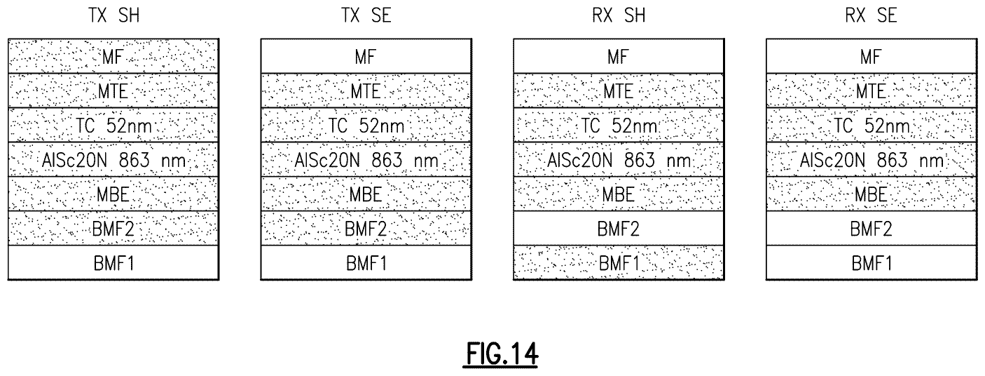

Another variation on the stack structure for a Band 3 duplexer illustrated in FIG. 11 is shown in FIG. 14. The variation illustrated in FIG. 14 differs from that illustrated in FIG. 11 in that the series resonators of the transmission filter utilize a BMF2 mass loading layer instead of an MF mass loading layer.

Another variation on the stack structure for a Band 3 duplexer illustrated in FIG. 11 is shown in FIG. 15. The variation illustrated in FIG. 15 differs from that illustrated in FIG. 11 in that the shunt resonators of the reception filter utilize a BMF2 mass loading layer instead of a BMF1 mass load layer. The variation illustrated in FIG. 15 also differs from that illustrated in FIG. 11 in that the series resonators of the transmission filter utilize a BMF1 mass loading layer instead of an MF mass loading layer and the shunt resonators of the transmission filter utilize a BMF1 mass loading layer instead of a BMF2 mass loading layer. The BMF2 mass loading layer is not present in the shunt resonators of the transmission filter so the BMF1 mass loading layer is the only dominant mass loading layer below the piezoelectric material layer of the transmission filter shunt resonators.

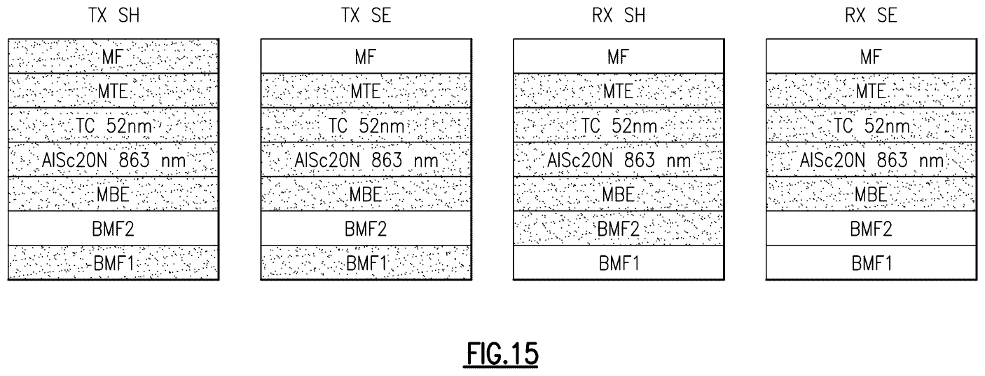

Another variation on the stack structure for a Band 3 duplexer illustrated in FIG. 11 is shown in FIG. 16. The variation illustrated in FIG. 16 differs from that illustrated in FIG. 11 in that the shunt resonators of the reception filter utilize an MF mass loading layer instead of a BMF1 mass loading layer. The variation illustrated in FIG. 16 also differs from that illustrated in FIG. 11 in that the series resonators of the transmission filter utilize a BMF1 mass loading layer instead of an MF mass loading layer and the shunt resonators of the transmission filter utilize a BMF1 mass loading layer instead of a BMF2 mass loading layer and do not utilize an MF mass loading layer. The BMF2 mass loading layer is not present in the series resonators of the transmission filter so the BMF1 mass loading layer is the only dominant mass loading layer below the piezoelectric material layer of the transmission filter series resonators.

The acoustic wave devices discussed herein can be implemented in a variety of filters and packaged modules. Some example packaged modules will now be discussed in which any suitable principles and advantages of the packaged acoustic wave devices discussed herein can be implemented. FIGS. 17, 18, 19, and 20 are schematic block diagrams of an illustrative filter and packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example.

In some embodiments, multiple BAW resonators as disclosed herein may be combined into a filter, for example, an RF ladder filter schematically illustrated in FIG. 17 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

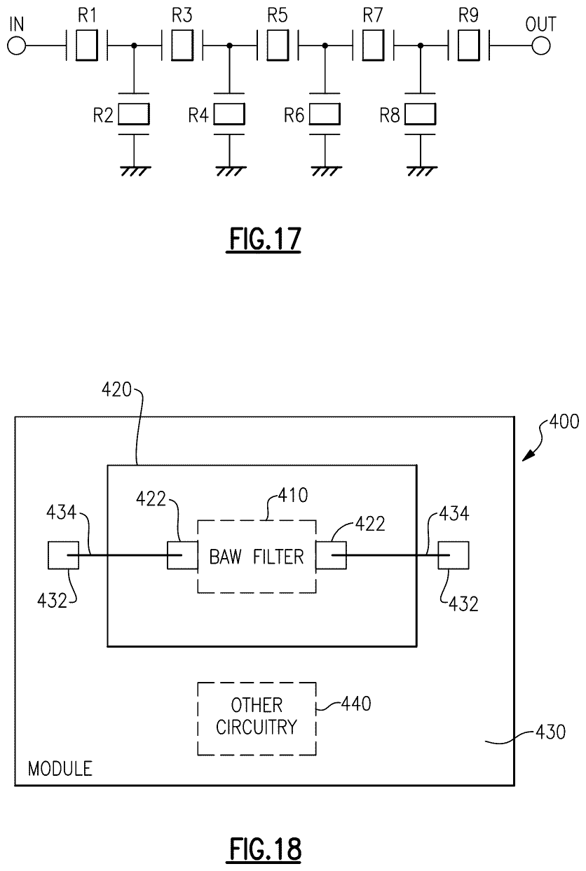

FIG. 18 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

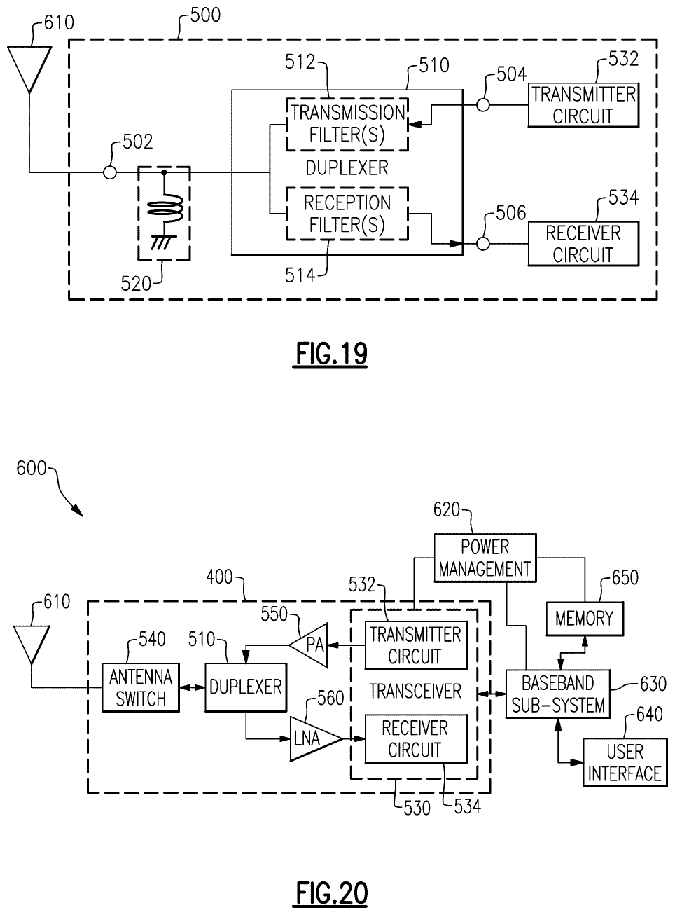

Referring to FIG. 19, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 19, however in other embodiments these components may be integrated into a common transceiver circuit or module. As will be appreciated by those skilled in the art, the front-end module 500 may include other components that are not illustrated in FIG. 19 including, but not limited to, switches, electromagnetic couplers, amplifiers, processors, and the like.

FIG. 20 is a block diagram of one example of a wireless device 600 including the antenna duplexer 510 shown in FIG. 19. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 19. The front-end module 500 includes the duplexer 510, as discussed above. In the example shown in FIG. 20 the front-end module 500 further includes an antenna switch 540, which can be configured to switch between different frequency bands or modes, such as transmit and receive modes, for example. In the example illustrated in FIG. 20, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 19.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 20, the front-end module 500 may further include a low noise amplifier module 560, which amplifies received signals from the antenna 610 and provides the amplified signals to the receiver circuit 534 of the transceiver 530.

The wireless device 600 of FIG. 20 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to”. The word “coupled,” as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A die comprising a plurality of bulk acoustic wave resonators, each of the plurality of bulk acoustic wave resonators including a piezoelectric material film having an active region, the plurality of bulk acoustic wave resonators including a first subset with metallic mass loading layers disposed above an upper electrode disposed on the piezoelectric material film in the active region and a second subset with metallic mass loading layers disposed below a lower electrode disposed on the piezoelectric material film in the active region to cause the first subset to exhibit a different operating frequency than the second subset.

2. The die of claim 1 wherein the plurality of bulk acoustic wave resonators form a first radio frequency filter and a second radio frequency filter, the first radio frequency filter and the second radio frequency filter having non-overlapping passbands.

3. The die of claim 2 wherein the first radio frequency filter and the second radio frequency filter form a duplexer.

4. The die of claim 2 wherein the first radio frequency filter and the second radio frequency filter are configured as ladder filters, each including series arm resonators and shunt arm resonators selected from among the plurality of bulk acoustic wave resonators.

5. The die of claim 4 wherein the shunt arm resonators of each of the first radio frequency filter and the second radio frequency filter have a same mass loading.

6. The die of claim 4 wherein the series arm resonators of each of the first radio frequency filter and the second radio frequency filter have a same mass loading.

7. The die of claim 2 wherein at least one bulk acoustic wave resonator in each of the first radio frequency filter and the second radio frequency filter includes a metallic mass loading layer disposed above the upper electrode disposed on the piezoelectric material film in the active region and at least one bulk acoustic wave resonator in each of the first radio frequency filter and the second radio frequency filter includes a metallic mass loading layer disposed below the lower electrode disposed on the piezoelectric material film in the active region.

8. The die of claim 7 wherein at least one series arm resonator in one of the first radio frequency filter or the second radio frequency filter includes the metallic mass loading layer disposed above the upper electrode disposed on the piezoelectric material film in the active region and at least one shunt arm resonator in the one of the first radio frequency filter or the second radio frequency filter includes the metallic mass loading layer disposed below the lower electrode disposed on the piezoelectric material film in the active region.

9. The die of claim 7 wherein at least one shunt arm resonator in one of the first radio frequency filter or the second radio frequency filter includes the metallic mass loading layer disposed above the upper electrode disposed on the piezoelectric material film in the active region and at least one series arm resonator in the one of the first radio frequency filter or the second radio frequency filter includes the metallic mass loading layer disposed below the lower electrode disposed on the piezoelectric material film in the active region.

10. The die of claim 2 wherein at least one shunt arm resonator of the first radio frequency filter includes a first metallic mass loading layer disposed above the upper electrode disposed on the piezoelectric material film in the active region and at least one shunt arm resonator of the second radio frequency filter includes a second metallic mass loading layer disposed above the upper electrode disposed on the piezoelectric material film in the active region, the first metallic mass loading layer having a different thickness than the second metallic mass loading layer.

11. The die of claim 2 wherein at least one shunt arm resonator of the first radio frequency filter includes a first metallic mass loading layer disposed above the upper electrode disposed on the piezoelectric material film in the active region and at least one shunt arm resonator of the second radio frequency filter includes a second metallic mass loading layer disposed below the lower electrode disposed on the piezoelectric material film in the active region, the first metallic mass loading layer having a different thickness than the second metallic mass loading layer.

12. The die of claim 2 wherein at least one shunt arm resonator of the first radio frequency filter includes a first metallic mass loading layer disposed above the upper electrode disposed on the piezoelectric material film in the active region and at least one series arm resonator of the second radio frequency filter includes a second metallic mass loading layer disposed below the lower electrode disposed on the piezoelectric material film in the active region, the first metallic mass loading layer having a different thickness than the second metallic mass loading layer.

13. The die of claim 2 wherein at least one shunt arm resonator of one of the first radio frequency filter or the second radio frequency filter includes two metallic mass loading layers disposed above the upper electrode disposed on the piezoelectric material film in the active region, the two metallic mass loading layers having different thicknesses.

14. The die of claim 2 wherein at least one shunt arm resonator one of the first radio frequency filter or the second radio frequency filter includes two metallic mass loading layers disposed below the lower electrode disposed on the piezoelectric material film in the active region, the two metallic mass loading layers having different thicknesses.

15. The die of claim 2 wherein at least one shunt arm resonator of one of the first radio frequency filter or the second radio frequency filter includes a metallic mass loading layer disposed below the lower electrode disposed on the piezoelectric material film in the active region and a metallic mass loading layer disposed above the upper electrode disposed on the piezoelectric material film in the active region.

16. The die of claim 2 wherein at least one shunt arm resonator of the first radio frequency filter includes a first metallic mass loading layer disposed below the lower electrode disposed on the piezoelectric material film in the active region and at least one shunt arm resonator of the second radio frequency filter includes a second metallic mass loading layer disposed below the lower electrode disposed on the piezoelectric material film in the active region, the first metallic mass loading layer having a different thickness than the second metallic mass loading layer.

17. The die of claim 2 wherein at least one shunt arm resonator of the first radio frequency filter includes a first metallic mass loading layer disposed below the lower electrode disposed on the piezoelectric material film in the active region and at least one series arm resonator of the second radio frequency filter includes a second metallic mass loading layer disposed below the lower electrode disposed on the piezoelectric material film in the active region, the first metallic mass loading layer having a different thickness than the second metallic mass loading layer.

18. The die of claim 1 wherein the plurality of bulk acoustic wave resonators include resonators which form parts of at least three different radio frequency filters with different operating frequencies.

19. An electronic device module including the die of claim 1.

20. A radio frequency device including the electronic device module of claim 19.
